(19) United States
(12) Patent Application Publication
(10) Pub. No.: US 2016/0122225 A1
(43) Pub. Date: May 5, 2016

(54) METHOD FOR MANUFACTURING GLASS PLATE HAVING CURVED SHAPE, GLASS PLATE HAVING CURVED SHAPE, AND MANUFACTURING APPARATUS FOR GLASS PLATE HAVING CURVED SHAPE

(71) Applicant: NIPPON ELECTRIC GLASS CO., LTD., Otsu-shi, Shiga (JP)

(72) Inventors: Masanori WADA, Otsu-shi (JP); Osamu ODANI, Otsu-shi (JP); Masayuki IKEMOTO, Otsu-shi (JP)

(21) Appl. No.: 14/895,697

(22) PCT Filed: Apr. 9, 2014
(86) PCT No.: PCT/JP2014/060272

§ 371 Date: Dec. 3, 2015

(30) Foreign Application Priority Data
Jul. 30, 2013 (JP) 2013-157243

(51) Int. Cl. C03B 23/023; H05K 5/03

(52) U.S. Cl. CPC C03B 23/023; C03B 23/0235; H05K 5/03

(57) ABSTRACT

Provided are a method that can manufacture a glass plate having a curved shape by a simple process and with high surface accuracy, a glass plate manufactured by the method, and an apparatus for manufacturing a glass plate having a curved shape. A method for manufacturing a glass plate having a curved shape includes the steps of: preparing an original glass plate (10); elastically deforming the original glass plate (10); and heating the original glass plate (10) being elastically deformed to plastically deform the original glass plate (10) and thus give the original glass plate (10) the curved shape.

### TECHNICAL FIELD

This invention relates to a method for manufacturing a glass plate having a curved shape, particularly a cylindrical surface, a glass plate having a curved shape obtained by the manufacturing method, and an apparatus for manufacturing a glass plate having a curved shape.

### BACKGROUND ART

Mobile devices with a display, including cellular phones, smartphones, notebook personal computers, and tablet personal computers, have recently been widely used. A display is also used in in-vehicle equipment, such as car-mounted navigation systems.

A cover glass is often used for a display used in such a mobile device and in-vehicle equipment as described above. A flat glass plate is generally used as such a cover glass. However, from the operability, aesthetic, and other viewpoints, there are cases where a glass plate having a curved shape is desired as the cover glass.

Conventionally, as described in Patent Literature 1, a glass plate having a curved shape is manufactured by placing a flat glass plate on a forming die having a curved shape, heating the glass plate to a temperature of the softening point thereof or above to soften it, and deforming it along the shape of the forming die under its own weight.

Patent Literature 2 discloses a method in which a coating film is formed on one side of a glass plate increased in temperature to the softening point and the glass plate is bent into a desired curved shape by a thermal contraction force of the formed coating film.

### CITATION LIST

### Patent Literature

### PTL 1

Examined Japanese Patent Application Publication No. S35-16443

### PTL 2

JP-A-H09-100130

### SUMMARY OF INVENTION

### Technical Problem

In the conventional method described in Patent Literature 1, the surface shape of the forming die is transferred to the glass plate, which deteriorates the surface accuracy of the glass plate. Therefore, in the case where the glass plate is used as a cover glass for a display or the like, there arises a problem in that the surface of the glass plate must be polished. In the conventional method described in Patent Literature 2, there arises the problem that the step of forming a coating film is required, which makes the manufacturing process cumbersome. Furthermore, there also arises the problem that a glass plate with no coating film cannot be manufactured.

An object of the present invention is to provide a method that can manufacture a glass plate having a curved shape by a simple process and with high surface accuracy, a glass plate manufactured by the method, and an apparatus for manufacturing a glass plate having a curved shape.

### Solution to Problem

The present invention is directed to a method for manufacturing a glass plate having a curved shape, the method including the steps of: preparing an original glass plate; elastically deforming the original glass plate; and heating the original glass plate being elastically deformed to plastically deform the original glass plate and thus give the original glass plate the curved shape.

A temperature at which the original glass plate is heated is preferably not lower than a strain point of glass forming the original glass plate and not higher than a softening point of the glass.

In a preferred embodiment of the present invention, the original glass plate is preferably elastically deformed by holding both ends of the original glass plate and then narrowing a distance between both the ends thereof.

Furthermore, the curved shape is preferably that of a cylindrical surface.

Moreover, in the present invention, the original glass plate is preferably plastically deformed without bringing the original glass plate into contact with any die.

The glass plate having a curved shape manufactured by the method according to the present invention is, for example, a glass plate for use as a display cover glass or a glass plate for use as a back cover glass for a mobile device.

A glass plate having a curved shape according to the present invention is a glass plate manufactured by the above-described method according to the present invention.

A manufacturing apparatus for a glass plate having a curved shape according to the present invention includes: an elastically deforming means configured to elastically deform an original glass plate; and a heating means configured to heat the original glass plate being elastically deformed to plastically deform the original glass plate and thus give the original glass plate the curved shape.

Furthermore, the elastically deforming means preferably includes a holding portion configured to hold both ends of the original glass plate and narrow a distance between both the ends thereof, thus elastically deforming the original glass plate.

The manufacturing apparatus preferably further includes a cooling means configured to cool the plastically deformed original glass plate.

### Advantageous Effects of Invention

The present invention can manufacture a glass plate having a curved shape by a simple process and with high surface accuracy.

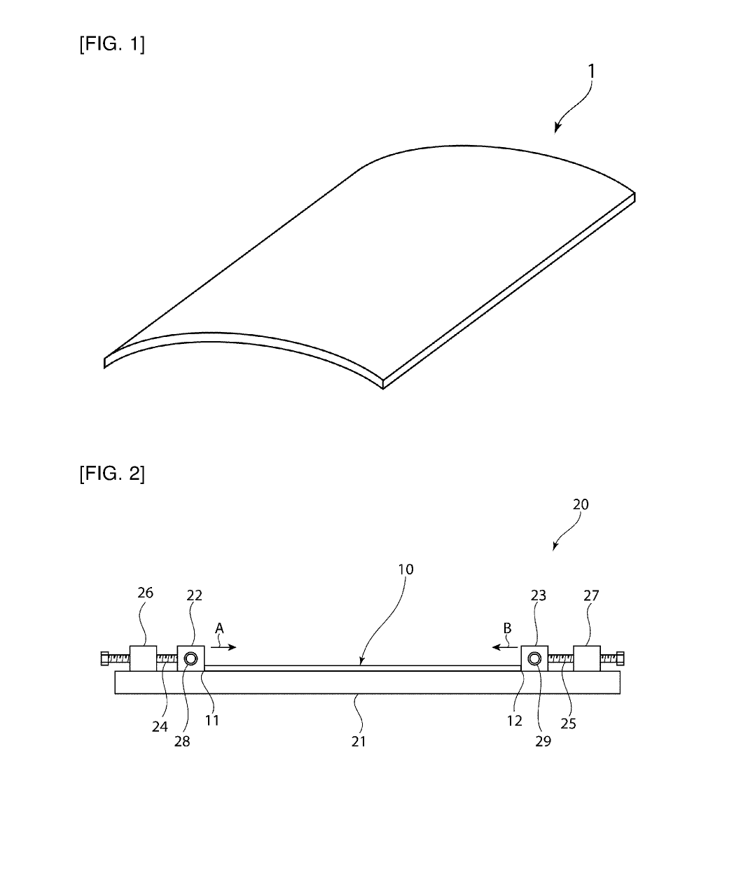

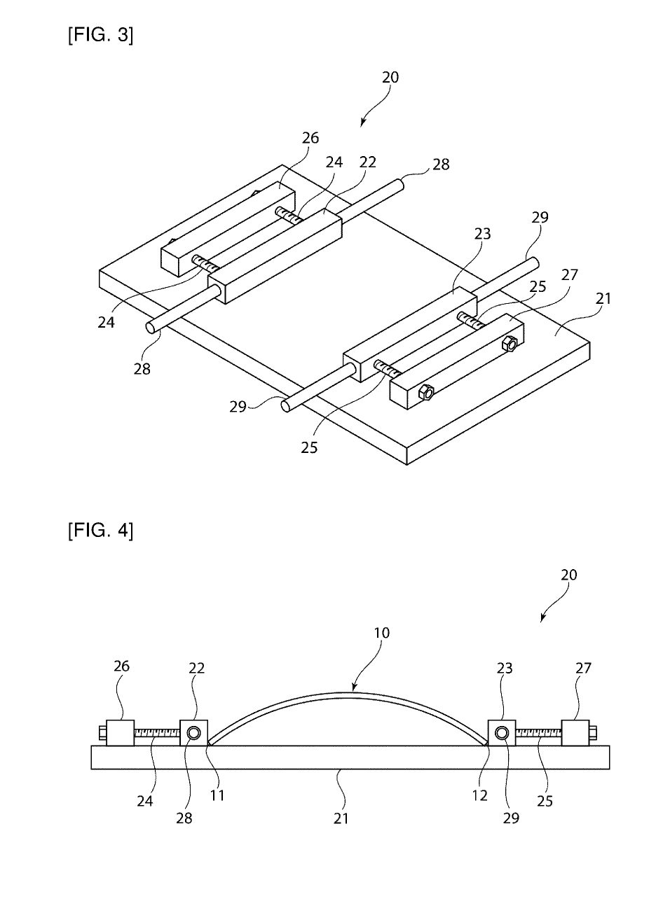

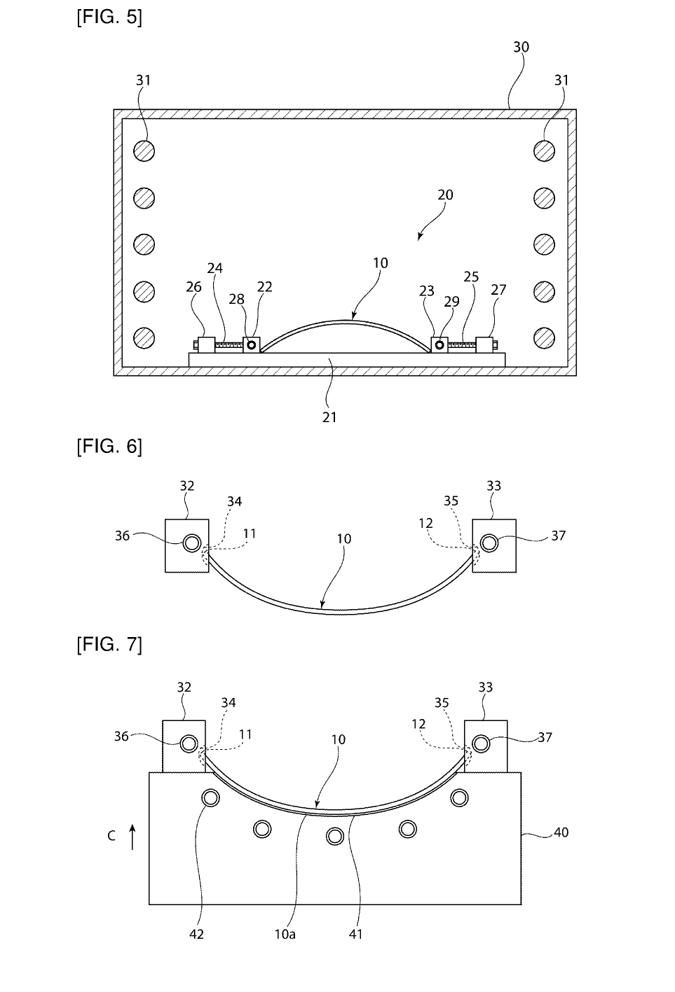

### BRIEF DESCRIPTION OF DRAWINGS

[Fig. 1] FIG. 1 is a perspective view showing an example of a glass plate having a curved shape according to the present invention.

[Fig. 2] FIG. 2 is a front view showing a state before the glass plate is elastically deformed in a first embodiment of the present invention.

[Fig. 3] FIG. 3 is a perspective view showing a tool for use in holding an original glass plate and elastically deforming it in the first embodiment of the present invention.

[Fig. 4] FIG. 4 is a front view showing a state of the original glass plate being elastically deformed in the first embodiment of the present invention.

[Fig. 5] FIG. 5 is a schematic cross-sectional view showing, in the first embodiment of the present invention, how the original glass plate being elastically deformed is placed in an electric furnace and heated.

[Fig. 6] FIG. 6 is a front view showing a state of an original glass plate being elastically deformed in a second embodiment of the present invention.

[Fig. 7] FIG. 7 is a front view showing, in the second embodiment of the present invention, how the original glass plate plastically deformed by heating the original glass plate being elastically deformed is cooled by bringing it into contact with the surface of a recess in a die.

### DESCRIPTION OF EMBODIMENTS

Hereinafter, a description will be given of preferred embodiments of the present invention. However, the following embodiments are merely illustrative and the present invention is not intended to be limited to the following embodiments. Throughout the drawings, elements having substantially the same functions may be referred to by the same reference signs.

FIG. 1 is a perspective view showing an example of a glass plate having a curved shape according to the present invention. A glass plate 1 having a curved shape shown in FIG. 1 has a curved surface having a curvature in a single direction, a so-called cylindrical surface, and particularly its cross section in the single direction has a cylindrical surface of a single radius of curvature. A manufacturing method according to the present invention can be applied to the manufacture of a glass plate 1 having a cylindrical surface as shown in FIG. 1. However, the present invention is not limited to the manufacture of such a glass plate but can be applied to the case of manufacturing a glass plate having an elliptic cylindrical surface, a hyperbolic cylindrical surface, a parabolic cylindrical surface or like cylindrical surface; a glass plate partly given a cylindrical surface; and a glass plate given a plurality of cylindrical surfaces.

FIG. 2 is a front view showing a state before the glass plate is elastically deformed in a first embodiment of the present invention.

As shown in FIG. 2, first, a flat original glass plate 10 is prepared and placed on a platen 21 of a tool 20. The original glass plate 10 is placed between a holding portion 22 and a holding portion 23. The tool 20 is configured as follows.

FIG. 3 is a perspective view showing the tool 20. The holding portion 22 for holding one end 11 of the original glass plate 10 and the holding portion 23 for holding the other end 12 thereof are provided on the platen 21. The holding portion 22 is attached through two screw portions 24 to a fixed portion 26. Likewise, the holding portion 23 is attached through two screw portions 25 to a fixed portion 27. The fixed portions 26 and 27 are fixed to the platen 21. The holding portion 22 can be moved on the platen 21 toward and away from the opposed holding portion 23 by turning the screw portions 24 in predetermined directions. The holding portion 23 can be likewise moved on the platen 21 toward and away from the opposed holding portion 22 by turning the screw portions 25 in predetermined directions.

The surface of the platen 21 coming into contact with the original glass plate 10 and the surfaces of the holding portions 22 and 23 are coated with cloth elastically deformable in a thickness direction, such as glass cloth, ceramic cloth or carbon fiber cloth. Coolant introduction pipes 28 and 29 are passed through the holding portions 22 and 23, respectively. The surfaces of the holding portions 22 and 23 can be cooled by allowing a coolant to flow through the coolant introduction pipes 28 and 29, respectively. The preferred coolant to be used is a gas such as air.

Next, as shown in FIG. 2, the original glass plate 10 is placed on the platen 21 of the tool 20 configured as described above. The original glass plate 10 is placed between the holding portion 22 and the holding portion 23, held at the one end 11 by the holding portion 22, and held at the other end 12 by the holding portion 23. In this state, the screw portions 24 are turned to move the holding portion 22 to a desired position in the direction of the arrow A and the screw portions 25 are turned to move the holding portion 23 to a desired position in the direction of the arrow B, so that, as shown in FIG. 4, the original glass plate 10 is elastically deformed to form thereon a cylindrical surface identical or similar to that of the glass plate 1. More specifically, the original glass plate 10 is elastically deformed by holding the original glass plate 10 at both end surfaces 11 and 12 and applying to both the end surfaces 11, 12 an external pressure in a direction approximately parallel with the principal surface of the original glass plate 10 before being elastically deformed. This step need not be accompanied by heating the original glass plate 10 but the original glass plate 10, if heated, is preferably controlled to have a temperature of up to the strain point of the original glass plate 10.

The original glass plate 10 only has to be thick enough to be elastically deformed. For example, the thickness is preferably in a range of 0.2 to 2 mm and more preferably in a range of 0.3 to 1.8 mm. Furthermore, the original glass plate 10 is not limited to have a flat shape but, for example, may have a shape having a curved surface. Next, the original glass plate 10 is heated in a state of being elastically deformed in the above manner, and thus plastically deformed.

FIG. 5 is a schematic cross-sectional view showing how the original glass plate being elastically deformed is placed in an electric furnace and heated. As shown in FIG. 5, the original glass plate 10 being elastically deformed is placed in an electric furnace 30. The electric furnace 30 is internally provided with a heater 31 and the interior of the electric furnace 30 can be heated to a predetermined temperature by the heater 31. The temperature at which the original glass plate 10 is heated is preferably not lower than a temperature at which the original glass plate 10 starts plastically deforming and below a temperature at which the original glass plate 10 starts softening and deforming under its own weight, and specifically not lower than the strain point of glass forming the original glass plate 10 and not higher than the softening point of the glass. More preferably, the temperature is not lower than the glass transition point of the glass and not higher than the softening point of the glass. The duration of heating is not particularly limited and only has to be a duration long enough to change the elastic deformation of the original glass plate 10 to plastic deformation. The duration of heating is generally, for example, in a range of ten minutes to five hours.

After being heated in the above manner, the original glass plate 10 is cooled. Thanks for the above heating, the cooled original glass plate 10 can be a glass plate 1 that, even when the external force being applied is removed, maintains the curved shape formed by the elastic deformation, i.e., is plastically deformed and given a curved shape (has a cylindrical surface formed).

In the present invention, a glass plate having a curved shape is manufactured by heating an original glass plate being elastically deformed to plastically deform the original glass plate. Therefore, a glass plate having a curved shape can be manufactured by a simple process. Furthermore, because no forming die is used unlike the conventional technique, it can be avoided that the surface shape of the forming die is transferred to the surface of the original glass plate. In this embodiment, the original glass plate is plastically deformed without, during heating, bringing the surface of the original glass plate into contact with any forming die. Therefore, a glass plate having a curved shape can be manufactured with high surface accuracy.

In the present invention, in cooling the heated original glass plate 10, the glass plate 10 may be cooled by bringing it into contact with a die. Hereinafter, a description will be given of such an embodiment as a second embodiment.

FIG. 6 is a front view showing a state of an original glass plate 10 being elastically deformed in the second embodiment of the present invention. One end 11 of the original glass plate 10 is held by a holder 32 and the other end 12 thereof is held by a holder 33. The holder 32 has a holding groove 34 formed therein and the one end 11 of the original glass plate 10 is set in the holding groove 34. Likewise, the holder 33 has a holding groove 35 formed therein and the other end 12 of the original glass plate 10 is set in the holding groove 35. Coolant introduction pipes 36 and 37 are passed through the holders 32 and 33, respectively, like the holding portions 22 and 23 in the first embodiment. Furthermore, like the holding portions 22 and 23 in the first embodiment, the surfaces of the holders 32 and 33 are coated with cloth elastically deformable in a thickness direction, such as glass cloth, ceramic cloth or carbon fiber cloth.

In the state shown in FIG. 6, the distance between the holder 32 and the holder 33 is reduced to narrow the distance between both ends 11, 12 of the original glass plate 10, thus applying an external force to both ends 11, 12 of the original glass plate 10 to elastically deform the original glass plate 10. In this case, without applying any external force to the original glass plate 10, the original glass plate 10 may be elastically deformed under its own weight. Like the first embodiment, the original glass plate 10 in this state is placed in an electric furnace 30 and heated therein.

FIG. 7 is a front view showing, in the second embodiment, how the original glass plate 10 plastically deformed by heating the original glass plate 10 being elastically deformed is cooled by bringing it into contact with the surface of a recess 41 in a die 40. As shown in FIG. 7, the die 40 is moved in the direction of the arrow C to bring the die 40 close to the original glass plate 10. The surface of the recess 41 in the die 40 is brought into contact with a raised surface 10a of the original glass plate 10 to cool the original glass plate 10. The surface of the recess 41 in the die 40 is coated with cloth, like the surfaces of the holders 32, 33. Furthermore, a plurality of coolant introduction pipes 42 are passed through the die 40. The die 40 is cooled by allowing a coolant to flow through the coolant introduction pipes 42 and the surface of the recess 41 is set to reach a predetermined temperature by the cooling. The surface temperature of the recess 41 is set at a temperature at which the original glass plate 10 plastically deformed by heating cannot be plastically deformed by contact with the recess 41 for a relatively short period of time, specifically a temperature lower than that of the original glass plate 10, and preferably a temperature lower than that of the original glass plate 10, not lower than the glass strain point, and not higher than the glass transition point minus 30° C. Therefore, the surface shape of the recess 41 is less likely to be transferred to the raised surface 10a of the original glass plate 10.

In the second embodiment, in cooling the heated original glass plate 10, the original glass plate 10 is cooled by bringing it into contact with the die 40. Therefore, the time taken for the manufacturing process can be shortened. Although in the second embodiment the die having a recess is used, the surface of the original glass plate 10 opposite to the surface 10a thereof may be cooled using a die having a raised portion conforming to the curved shape of the original glass plate 10.

In the present invention, the original glass plate 10 is preferably heated as it is held in a curved shape on the platen 21 while being moved through a continuous heat treating furnace. Thus, a large number of original glass plates 10 can be efficiently heated.

The glass plate 1 having a curved shape according to the present invention can be used as a display cover glass for use in mobile devices, such as cellular phones, smartphones, notebook personal computers, and tablet personal computers, and in-vehicle equipment, such as car-mounted navigation systems, or as a back cover glass for use in mobile devices. In the case of use as a display cover glass, the curved surface can be a portion of a display on which an image is displayed.

### REFERENCE SIGNS LIST

1 . . . glass plate having a curved shape
10 . . . original glass plate
10a . . . surface
11 . . . one end
12 . . . the other end
20 . . . tool
21 . . . platen
22, 23 . . . holding portion
24, 25 . . . screw portion
26, 27 . . . fixed portion
28, 29 . . . coolant introduction pipe
30 . . . electric furnace
31 . . . heater
32, 33 . . . holder
34, 35 . . . holding groove
36, 37 . . . coolant introduction pipe
40 . . . die
41 . . . recess
42 . . . coolant introduction pipe

1. A method for manufacturing a glass plate having a curved shape, the method comprising the steps of:
preparing an original glass plate;
elastically deforming the original glass plate; and
heating the original glass plate being elastically deformed to plastically deform the original glass plate and thus give the original glass plate the curved shape.

2. The method for manufacturing a glass plate having a curved shape according to claim 1, wherein a temperature at which the original glass plate is heated is not lower than a strain point of glass forming the original glass plate and not higher than a softening point of the glass.

3. The method for manufacturing a glass plate having a curved shape according to claim 1, wherein the original glass plate is elastically deformed by holding both ends of the original glass plate and then narrowing a distance between both the ends thereof.

4. The method for manufacturing a glass plate having a curved shape according to claim 1, wherein the curved shape is that of a cylindrical surface.

5. The method for manufacturing a glass plate having a curved shape according to claim 1, wherein the original glass plate is plastically deformed without bringing the original glass plate into contact with any die.

6. The method for manufacturing a glass plate having a curved shape according to claim 1, wherein the glass plate having a curved shape is a glass plate for use as a display cover glass.

7. The method for manufacturing a glass plate having a curved shape according to claim 1, wherein the glass plate having a curved shape is a glass plate for use as a back cover glass for a mobile device.

8. A glass plate having a curved shape manufactured by the method according to claim 1.

9. A manufacturing apparatus for a glass plate having a curved shape, the manufacturing apparatus comprising:
an elastically deforming means configured to elastically deform an original glass plate; and
a heating means configured to heat the original glass plate being elastically deformed to plastically deform the original glass plate and thus give the original glass plate the curved shape.

10. The manufacturing apparatus for a glass plate having a curved shape according to claim 9, wherein the elastically deforming means comprises a holding portion configured to hold both ends of the original glass plate and narrow a distance between both the ends thereof, thus elastically deforming the original glass plate.

11. The manufacturing apparatus for a glass plate having a curved shape according to claim 9, further comprising a cooling means configured to cool the plastically deformed original glass plate.
